(19) United States
(12) Patent Application Publication
(10) Pub. No.: US 2010/0184241 A1
(43) Pub. Date: Jul. 22, 2010

(54) METHOD FOR MANUFACTURING THIN TYPE LIGHT EMITTING DIODE ASSEMBLY

(75) Inventors: SHIH-TAI CHUANG, TAIPEI CITY (TW); LI-JEN HO, TAIPEI HSIEN (TW)

Correspondence Address: ROSENBERG, KLEIN & LEE, 3458 ELLICOTT CENTER DRIVE-SUITE 101, ELLICOTT CITY, MD, 21043, US

(73) Assignee: EDISON OPTO CORPORATION, TAIPEI HSIEN (TW)

(21) Appl. No.: 12/355,117

(22) Filed: Jan. 16, 2009

(51) Int. Cl. H01L 33/00

(52) U.S. Cl. 438/26; 257/E33.059

(57) ABSTRACT

A method is applied to manufacture a thin type light emitting diode (LED) assembly, and comprises the steps of: pressing a light-transmissible conductive film onto a carrier; etching an etched circuit on the light-transmissible conductive film to form an etched light-transmissible conductive film; bonding a LED chip on the etched light-transmissible conductive film to make the LED chip electrically connected with the etched circuit; covering the LED chip and the etched light-transmissible conductive film with a light-transmissible encapsulation layer to encapsulate the LED chip therein; and cutting the carrier to make the carrier be removed from the etched light-transmissible conductive film, so as to manufacture the thin type LED assembly.

### FIELD OF THE INVENTION

The present invention relates to a method for manufacturing a light emitting diode (LED) assembly, and more particularly to method for manufacturing a thin type LED assembly.

### BACKGROUND OF THE INVENTION

In daily life, for identifying objects and directions in dark environment, it is usually necessary to provide illumination for us via the utilization of a light emitting assembly. Among the light emitting assemblies, LED has become the most popular light emitting assembly gradually due to global energy saving trend and its advantages of long usage life and low power consumption.

However, besides the usage of wide-field illumination, due to that the LED has the advantages of long usage life and low power consumption, LED is also usually applied to be assembled into the LED assembly to provide for the backlight of the electronic devices or for other utilization. Furthermore, in the practical applications, the electronic device is requested to be lighter and thinner, so that the application of LED assemblies is developed toward the aspect of lighter weight and thinner thickness.

Based on the background as mentioned, following up, a representative technology for manufacturing the conventional LED assembly in prior art is disclosed for more detail illustration. Please refer to the drawings from FIG. 1 to FIG. 1G, which illustrate a series of steps for manufacturing the conventional LED assembly in prior arts. As shown in the drawings, in the prior art, it is necessary to prepare a metallic plate as a substrate layer 11 (as shown in FIG. 1), and necessary to form a dielectric layer 12 by plating (as shown in FIG. 1A). In the practical application, the metallic plate usually can be an alumina plate, a copper plate or any other alloy plate made of alumina and copper. Besides, in other prior arts, the non-metallic plates (e.g. the glass fiber plate or the ceramic plate) is also applied to be the substrate layer, while it is not necessary to do more discussion of the non-metallic plate due to that it is less related to the present invention.

After preparing the substrate layer 11, it is able to etch the dielectric layer 12 in accordance with the requirement of the circuit design and heat dissipation, so as to form an etched dielectric layer 12′ (as shown in FIG. 1B). Following up, it is able to form a metallic conductive layer 13 by a plating or vacuum film-plating method (as shown in FIG. 1C), and further etch an etched circuit (not shown) on metallic conductive layer 13 in accordance with the requirement of the circuit design and heat dissipation, so as to form an etched metallic conductive layer 13′ (as shown in FIG. 1D).

Next, it is able to arrange at least one LED chip 14 (as shown in FIG. 1E) on the etched metallic conductive layer 13′, and electrically connect each electrode of the LED chip 14 to the etched circuit of the etched metallic conductive layer 13′via bonding at least one lead wire 15 (as shown in FIG. 1F).

Finally, it is able to cover the LED chip 14 with a light-transmissible gel. After the light-transmissible gel is solidified, the light-transmissible encapsulation layer 16 is formed to encapsulate the LED chip 14, so as to manufacture the LED assembly 1 (as shown in FIG. 1G).

However, any person skilled in the arts can easily realize that in the prior art as disclosed above, although it is also able to manufacture the LED assembly 1, there are still two disadvantages difficult to be solved with regard to the LED assembly 1 manufactured according to the prior art.

First, in the processes of manufacturing the LED assembly 1, it is necessary to form the substrate layer 11, the etched dielectric layer 12′, the etched metallic conductive layer 13′ and the light-transmissible encapsulation layer 16 in sequence; therefore, the thickness of the LED assembly 1 is thicker after the LED assembly 1 is manufactured. Obviously, the prior art can not meet the requirement of thin thickness in practical application.

Second, in the LED assembly 1, the LED chip 14 is arranged on the etched metallic conductive layer 13′; therefore, only in the upper side, the light beam can be emitted, while in the lower side, the emitting path of the light beam is blocked by the etched metallic conductive layer 13′, the etched dielectric layer 12′ and the substrate layer 11. Obviously, the overall efficiency of light emitting is decreased in the prior arts as mentioned.

### SUMMARY OF THE INVENTION

Due to that the LED assembly of prior art exists the problem of thick thickness and only capable of single-directional light emitting, the primary objective of the present invention provides a method for manufacturing a new LED assembly, in which a separable carrier is applied for a transitional component to make the conductive layer be thin enough to reach the thickness grade of film, so as to decrease the overall thickness of the LED assembly.

Meanwhile, through the method as mentioned, another objective of the present invention is provided for decreasing the thickness of the conductive layer to the thickness grade of film. Preferably, due to that the thickness of the conductive layer is decreased to the thickness grade of film, the LED chip not only can emit the light beam through the light-transmissible encapsulation layer, but also can emit another light beam through the conductive layer, so as to achieve the objective of bi-directional light emitting.

Means of the present invention for solving the problems as mentioned above provides a method for manufacturing a thin type LED assembly, the method comprises the steps of: pressing a light-transmissible conductive film onto a carrier; etching an etched circuit on the light-transmissible conductive film to form an etched light-transmissible conductive film; bonding a LED chip on the etched light-transmissible conductive film to make the LED chip electrically connected with the etched circuit; covering the LED chip and the etched light-transmissible conductive film with a light-transmissible encapsulation layer to encapsulate the LED chip therein; and cutting the carrier to make the carrier be removed from the etched light-transmissible conductive film, so as to manufacture the thin type LED assembly.

Comparing with the conventional method for manufacturing the LED assembly as disclosed in prior arts, in the present invention, a separable carrier is applied for a transitional component to make the conductive layer (i.e., the etched light-transmissible conductive film) be thin enough to reach the thickness grade of film, so as to make the overall thickness of the LED assembly meet the requirement of thin thickness. Therefore, the method for manufacturing the thin type LED assembly as provided by the present invention can overcome the limitation of the specification and further widely apply to the field of manufacturing many kinds of light and thin electronic devices.

Preferably, through the method of the present invention as mentioned, the conductive layer (i.e., the etched light-transmissible conductive film) being thin to the thickness grade of film can also make the light beam emitted from the LED chip to transmit through the conductive layer, so as to fulfill the objective of bi-directional light emitting and further improve the overall efficiency of light emitting.

The devices, characteristics, and the preferred embodiment of this invention are described with relative figures as follows.

### BRIEF DESCRIPTION OF THE DRAWINGS

The structure and the technical means adopted by the present invention to achieve the above and other objectives can be best understood by referring to the following detailed description of the preferred embodiments and the accompanying drawings, wherein

FIG. 1 to FIG. 1G illustrate a series of steps for manufacturing the conventional LED assembly in prior arts;

FIG. 2 to FIG. 2F illustrate a series of steps for manufacturing the thin type LED assembly in accordance with the preferred embodiment of the present invention; and

FIG. 3 illustrates a simplified flowchart of the preferred embodiment of the present invention.

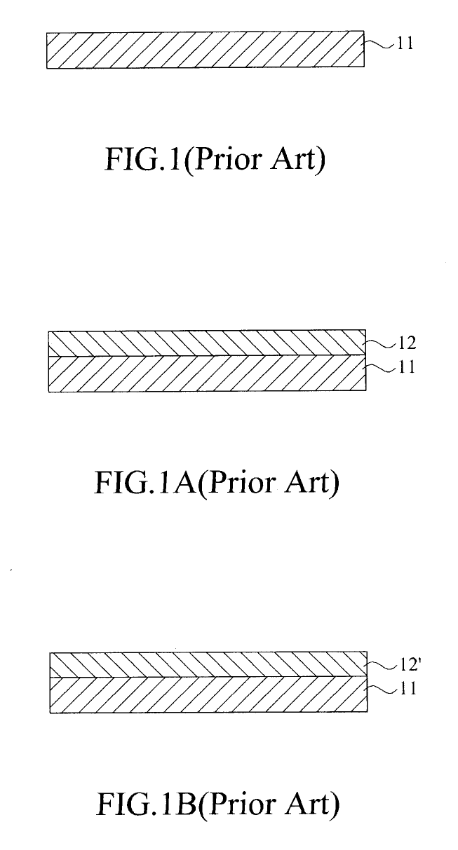

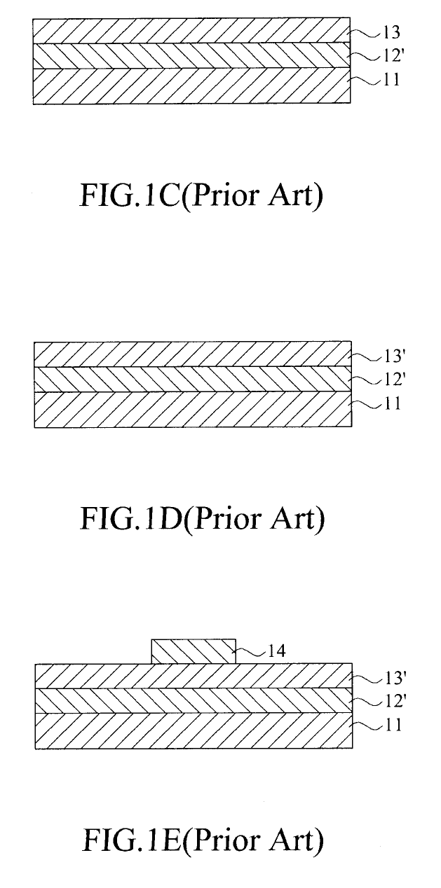

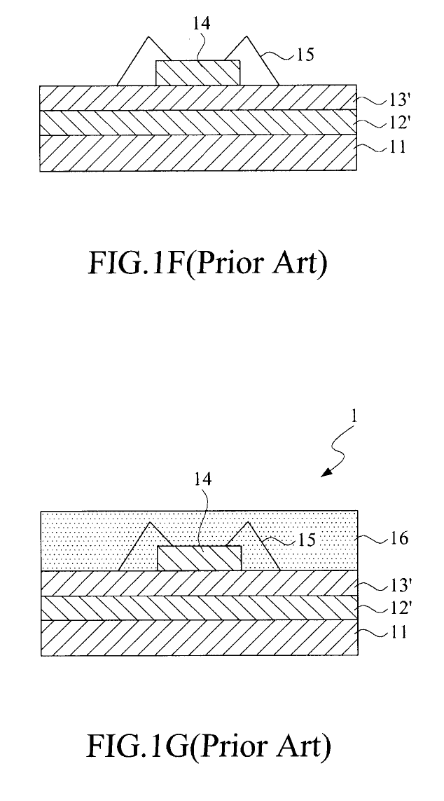

### DETAILED DESCRIPTION OF THE PREFERRED EMBODIMENTS

The method for manufacturing the thin type LED assembly as provided in accordance with the present invention can be widely applied to manufacture many kinds of thin LED assembly, and further applied to manufacture many kinds of thin electronic devices. Obviously, the combined applications of the present invention are too numerous to be enumerated and described, so that only one preferred embodiment is disclosed as follows for representation.

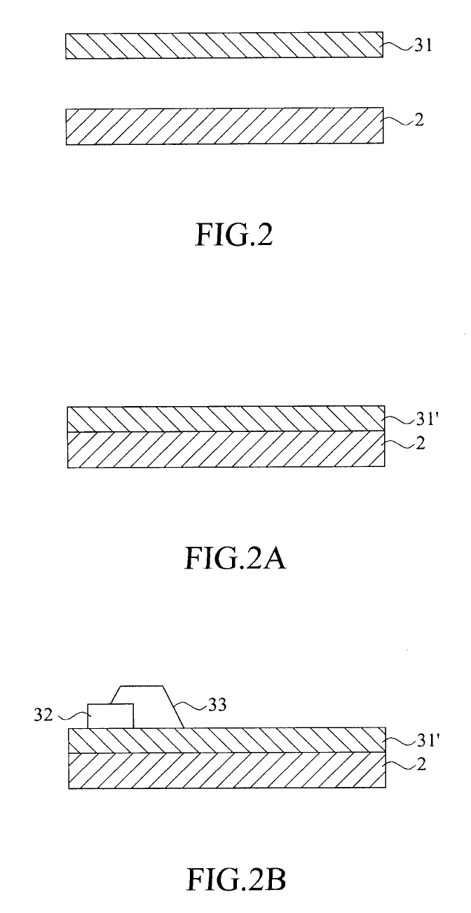

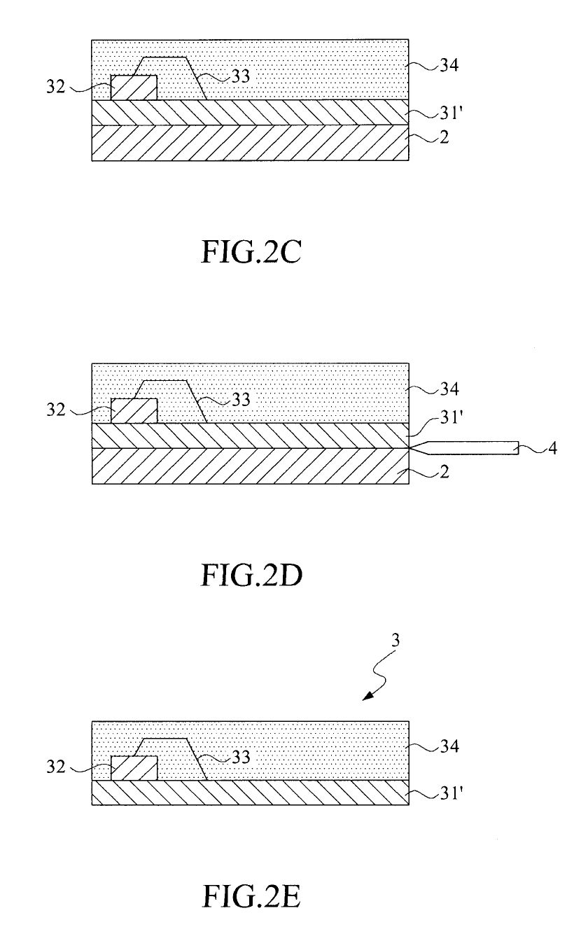

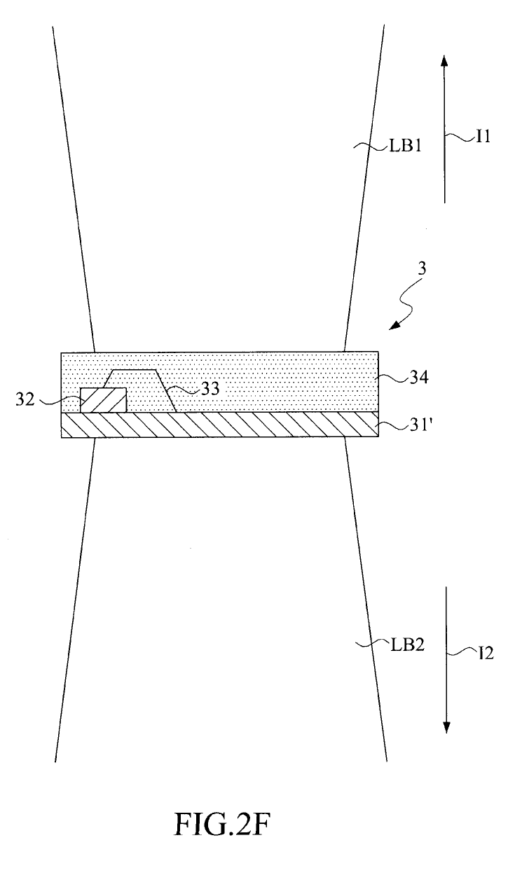

Please refer to the drawing from FIG. 2 to FIG. 2F, which illustrate a series of steps for manufacturing the thin type LED assembly accordance with the preferred embodiment of the present invention. As shown in the drawings, in the preferred embodiment of the present invention, it is necessary to prepare a carrier 2, and press a light-transmissible conductive film 31 onto the carrier 2 (as shown in FIG. 2). In the practical application, the carrier 2 can be a metallic plate or a non-metallic plate; preferably, the carrier 2 can be a steel plate.

After pressing a light-transmissible conductive film 31 onto the carrier 2, it is able to etch an etched circuit (not shown) on the light-transmissible conductive film 31 to form an etched light-transmissible conductive film 31′ (as shown in FIG. 2A). In practice, it is able to etch the etched circuit on the light-transmissible conductive film 31 via a chemical etching process or an optical etching process. Moreover, the light-transmissible conductive film 31 can be a conductive metallic film; preferably, the conductive metallic film can be a copper foil.

Following up, it is able to arrange at least one LED chip 32 on the etched light-transmissible conductive film 31′, and electrically connect each electrode of the LED chip 32 to the etched circuit of the etched light-transmissible conductive film 31 ′ via bonding at least one lead wire 15 (as shown in FIG. 2B).

Next, it is able to cover the LED chip 32 with a light-transmissible gel. After the light-transmissible gel is solidified, the light-transmissible encapsulation layer 34 is formed to encapsulate the LED chip 32 (as shown in FIG. 2C). In practical application, the light-transmissible gel can be a light-transmissible polymer; preferably, the light-transmissible polymer can be made of an epoxy resin material. In some specified application, it is able to make the epoxy resin material contain fluorescent powder, so as to stimulate the light beam emitted from the LED chip 32. For example, the fluorescent powder can be stimulated to project a white light beam when the LED chip 32 can emit a blue light beam, and the fluorescent powder is yellow phosphor powder.

Finally, a cutter 4 can be applied to remove the carrier 2 from the etched light-transmissible conductive film 31′; hereinafter, the whole procedure for manufacturing the (thin type) LED assembly 3 is completed. In other words, the LED assembly 3 of the present invention comprises the etched light-transmissible conductive film 31′, the LED chip 32, the lead wire 33 and the light-transmissible encapsulation layer 34 in accordance with the connection relation as mentioned above.

As presented in FIG. 2F, after completing manufacturing the LED assembly 3, the light-transmissible layer 34 is made of a solidified light-transmissible gel, therefore, a light beam LB1 emitted from the LED chip 32 can be projected through the light-transmissible layer 34 along a first projecting direction I1. Preferably, the thickness of the light-transmissible conductive film 31 is reduced to the thickness grade of film, therefore, another light beam LB2 emitted from the LED chip 32 also can be projected through the etched light-transmissible conductive film 31′, manufactured by etching the light-transmissible conductive film 31, along a second projecting direction I2, so as to carry out the function of bi-directional light emitting.

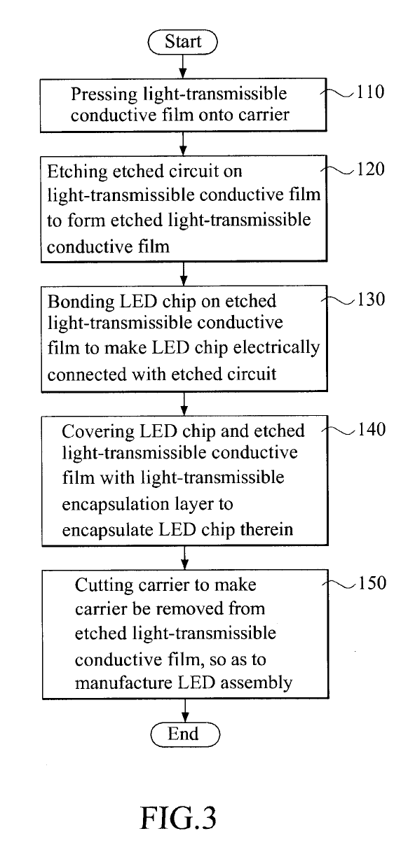

For making any person skilled in the arts be able to realize the method for manufacturing the thin type LED assembly as provide in the preferred embodiment of the present invention, following up, all steps of the method are summarized to a simplified flowchart for any person to easily memorize. Please refer to FIG. 3, which illustrates the simplified flowchart in accordance with the preferred embodiment of the present invention. As presented in FIG. 3, when manufacturing the LED assembly 3 in accordance with the preferred embodiment of the present invention, it is necessary to press a light-transmissible conductive film 31 onto the carrier (step 110), and etch the etched circuit on the light-transmissible conductive film 31 to form a etched light-transmissible film 31′ (step 120).

Next, it is able to bond the LED chip 32 on the etched light-transmissible conductive film 31′ to make each electrode of the LED chip 32 electrically connect to the etched circuit of the etched light-transmissible conductive film 31′ (step 130). Following up, it is able to cover the LED chip 32 with the light-transmissible encapsulation layer 34, so as to encapsulate the LED chip 32 (step 140). Finally, a cutter 4 can be applied to remove the carrier 2 from the etched light-transmissible conductive film 31′, so as to make the LED assembly 3 (step 150).

After reading the technology as disclosed in the present invention, any person skilled in the arts can easily realize that in the present invention, a separable carrier 2 is applied to be a transitional component to make the conductive layer (i.e., the etched light-transmissible conductive film) be thin to the thickness grade of film (approximate to the thickness of 20-100 μm), and further make to overall thickness of the LED assembly be thin to the thickness less than 0.2 mm; therefore, the method for manufacturing the LED assembly 3 as provided by the present invention can overcome the limitation of the specification and further widely apply to the field of manufacturing many kinds of light and thin electronic devices.

Nevertheless, through the method of the present invention as mentioned, the light-transmissible conductive film 31 can be reduced to the thickness grade of film (approximate to the thickness of 20-100 μm); therefore, after the light-transmissible conductive film 31 is etched to form the etched light-transmissible conductive film 31′, the LED chip 32 not only can emit the light beam through the light-transmissible encapsulation layer 34, but also can emit another light beam through the etched light-transmissible conductive film 31′. Obviously, the method as provided in the present invention can make the LED assembly 3 achieve the objective of bi-directional light emitting, and further improve the whole efficiency of light emitting.

Finally, it is necessary to emphasize that the light-transmissible conductive film 31 herein at least implies two arrangements; wherein the first arrangement is that the light-transmissible conductive film 31 itself is made of a conductive material with high efficiency of light-transmission; and the other arrangement is that the light-transmissible conductive film 31 itself is made of a conductive material with low efficiency of light-transmission and is thin enough to achieve the function of light-transmission. Furthermore, via the etching process, some predetermined slots, cracks, holes or gaps could be generated to make the etched light-transmissible conductive film 31 ′ perform higher efficiency of light-transmission.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A method being applied to manufacture a thin type light emitting diode (LED) assembly, and comprising the steps of:
(a) pressing a light-transmissible conductive film onto a carrier;
(b) etching an etched circuit on the light-transmissible conductive film to form an etched light-transmissible conductive film;
(c) bonding a LED chip on the etched light-transmissible conductive film to make the LED chip electrically connected with the etched circuit;
(d) covering the LED chip and the etched light-transmissible conductive film with a light-transmissible encapsulation layer to encapsulate the LED chip therein; and
(e) cutting the carrier to make the carrier be removed from the etched light-transmissible conductive film, so as to manufacture the LED assembly.

2. The method as claimed in claim 1, wherein the carrier is a metallic plate.

3. The method as claimed in claim 2, wherein the metallic plate is a steel plate.

4. The method as claimed in claim 1, wherein the carrier is a non-metallic plate.

5. The method as claimed in claim 1, wherein the light-transmissible conductive film is a conductive metal film.

6. The method as claimed in claim 5, wherein the conductive metal film is a copper foil.

7. The method as claimed in claim 1, wherein in the step (b), the etched circuit is etched by a chemical etching process.

8. The method as claimed in claim 1, wherein in the step (b), the etched circuit is etched by an optical etching process.

9. The method as claimed in claim 1, wherein in the step (d), the light-transmissible encapsulation layer is made of a solidified light-transmissible gel.

10. The method as claimed in claim 9, wherein the light-transmissible gel is a light-transmissible polymer.

11. The method as claimed in claim 10, wherein the light-transmissible polymer is an epoxy resin material.

12. The method as claimed in claim 11, wherein the epoxy resin material contains fluorescent powder.

13. The method as claimed in claim 1, wherein in the step (e), a cutter is applied to cut the carrier to make the carrier be removed from the etched light-transmissible conductive film.
